(19) United States
(12) Patent Application Publication
(10) Pub. No.: US 2025/0031344 A1
(43) Pub. Date: Jan. 23, 2025

(54) MICROCHANNEL ASSEMBLY COOLED POWER CIRCUITS FOR POWER BOXES OF SUBSTRATE PROCESSING SYSTEMS

(71) Applicant: LAM RESEARCH CORPORATION, Fremont, CA (US)

(72) Inventors: Ankur PANDEY, Bangalore (IN); Sam Sadrick GOMES, Bangalore (IN); Arun KESHAVAMURTHY, Bangalore (IN)

(21) Appl. No.: 18/701,808

(22) PCT Filed: Oct. 20, 2022
(86) PCT No.: PCT/US2022/047197

§ 371 Date: Apr. 16, 2024

Related U.S. Application Data
(60) Provisional application No. 63/271,636, filed on Oct. 25, 2021.

(51) Int. Cl. H05K 7/20; H01L 21/67

(52) U.S. Cl. CPC H05K 7/20272; H05K 7/20927; H01L 21/67011

(57) ABSTRACT

A cooling system for a power circuit of a substrate processing tool is provided. The cooling system includes a microchannel assembly and a printed circuit board. The microchannel assembly includes an input manifold, an output manifold, and a microchannel layer. The microchannel layer includes microchannels extending from the input manifold to the output manifold and configured to pass a coolant from the input manifold to the output manifold. The printed circuit board includes at least one component carrying layer, where the component carrying layer is attached to the microchannel layer between the input manifold and the output manifold. The at least one component carrying layer includes the power circuit including electrical components configured to power one or more electrical components of the substrate processing tool.

### CROSS-REFERENCE TO RELATED APPLICATIONS

This application claims the benefit of U.S. Provisional Application No. 63/271,636, filed on Oct. 25, 2021. The entire disclosure of the above application is incorporated herein by reference.

### FIELD

The present disclosure relates to cooling systems for AC power sources of substrate processing tools.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

A substrate processing system may be used to perform deposition, etch and/or other treatments of substrates such as semiconductor wafers. During processing, a substrate is arranged on a substrate support in a processing chamber of the substrate processing system. Gas mixtures including one or more precursors may be introduced into the processing chamber and plasma may be struck to activate chemical reactions.

The substrate processing system may include substrate processing tools arranged within a fabrication room. Each of the substrate processing tools may include multiple process modules or chambers. Each of the processing tools performs a single type of process, such as a clean, deposition or etch process. Substrates are transferred into a substrate processing tool through one or more intermediate chambers, such as front opening unified pods (FOUPs), an equipment front end module (EFEM), and/or load locks. The substrates are transferred between process modules within a vacuum transfer module (VTM). The substrate processing tools include various electronic components, devices and systems that received power from alternating current (AC) power sources.

### SUMMARY

A cooling system for a power circuit of a substrate processing tool is provided. The cooling system includes a microchannel assembly and a printed circuit board. The microchannel assembly includes an input manifold, an output manifold, and a microchannel layer. The microchannel layer includes microchannels extending from the input manifold to the output manifold and configured to pass a coolant from the input manifold to the output manifold. The printed circuit board includes at least one component carrying layer, where the component carrying layer is attached to the microchannel layer between the input manifold and the output manifold. The at least one component carrying layer includes the power circuit including electrical components configured to power one or more electrical components of the substrate processing tool.

In other features, the microchannel layer is disposed between layers of the printed circuit board such that the microchannel layer is embedded in the printed circuit board. In other features, the at least one component carrying layer includes: a first component carrying layer disposed on a first side of the microchannel layer; and a second component carrying layer disposed on a second side of the microchannel layer opposite the first side.

In other features, the cooling system further includes: a first conductive layer including a first pattern of conductive traces and disposed between the microchannel layer and the first component carrying layer; and a second conductive layer including a second pattern of conductive traces and disposed between the microchannel layer and the second component carrying layer. In other features, the cooling system further includes an alternating current box. The microchannel assembly and the printed circuit board are mounted on a same inner sidewall of the alternating current box.

In other features, the alternating current box is hermetically sealed. In other features, the microchannels include sets of microchannels. Distances between the sets of microchannels are greater than distances between microchannels in each of the sets of microchannels. In other features, the sets of microchannels include different numbers of microchannels.

In other features, the cooling system further includes conductive layers and vias. The at least one component carrying layer includes component carrying layers. The conductive layers are disposed between the microchannel layer and the component carrying layers. The vias extend through the microchannel layer in spaces between sets of the microchannels and contacting conductive traces of the conductive layers.

In other features, the microchannels are linear-shaped. In other features, the microchannels have a sinusoidal shape.

In other features, the cooling system further includes: a pump configured to circulate the coolant through the microchannel assembly; and a controller configured to select operating in a laminar flow mode or a turbulent flow mode and operate the pump accordingly.

In other features, a cooling system for a power circuit of a substrate processing tool. The cooling system includes a microchannel assembly and multiple printed circuit board layers. The microchannel assembly includes an input manifold, an output manifold, and a microchannel member. The microchannel member includes microchannels extending from the input manifold to the output manifold and configured to pass a coolant from the input manifold to the output manifold. The printed circuit board layers include a first printed circuit board layer and a second printed circuit board layer. The first printed circuit board layer is disposed on a first side of the microchannel member. The second printed circuit board layer is disposed on a second side of the microchannel member. The printed circuit board layers include the power circuit including electrical components configured to power one or more electrical components of the substrate processing tool.

In other features, the first printed circuit board layer includes a first component carrying layer and a first conductive layer. The second printed circuit board layer a second component carrying layer and a second conductive layer. In other features, the first conductive layer includes a first pattern of conductive traces. The second conductive layer includes a second pattern of conductive traces.

In other features, the microchannel member includes: flanges configured to connect to the input manifold and the output manifold; and a center member extending between the flanges and including the microchannels. In other features, the flanges and the center member are integrally formed as a single component.

In other features, the flanges extend perpendicular relative to the center member. The flanges and the center member have an ‘H’-shaped cross-section. In other features, the cooling system further includes gaskets disposed between the flanges and the input manifold and the output manifold. In other features, the cooling system further includes O-rings disposed between the flanges and the input manifold and the output manifold. In other features, the input manifold, the output manifold and the microchannel member are integrally formed as a single component.

In other features, the microchannels are linear-shaped. In other features, the microchannels have a sinusoidal shape.

In other features, the cooling system further includes: a pump configured to circulate the coolant through the microchannel assembly; and a controller configured to select operating in a laminar flow mode or a turbulent flow mode and operate the pump accordingly.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is an example substrate processing tool;

FIG. 2 is a plan view of another example substrate processing tool;

FIG. 3 is a functional block diagram of an example power system for a substrate processing tool including an example alternating current (AC) power box in accordance with the present disclosure;

FIG. 4 is an example microchannel assembly in accordance with the present disclosure;

FIG. 5 is an exploded view of a portion of a microchannel assembly cooled power circuit illustrating microchannel, conductive and printed circuit board layers in accordance with the present disclosure;

FIG. 6 is a perspective view of an example portion of a microchannel assembly illustrating sets of microchannels disposed between a pair of manifolds in accordance with the present disclosure;

FIG. 7 is an example temperature distribution diagram for a microchannel assembly similar to that shown in FIG. 6;

FIG. 8A is a perspective view of an example AC power box including an exploded view of an example of a microchannel assembly cooled power circuit in accordance with the present disclosure;

FIG. 8B is a perspective view of the AC power box of FIG. 7B with the microchannel assembly cooled power circuit attached to a sidewall of the AC power box;

FIG. 9A is a perspective view of another example microchannel assembly cooled power circuit with gasket sealed manifolds in accordance with the present disclosure;

FIG. 9B is an exploded view of the microchannel assembly cooled power circuit of FIG. 8A;

FIG. 10A is a perspective view of another example microchannel assembly cooled power circuit with O-ring sealed manifolds in accordance with the present disclosure;

FIG. 10B is an exploded view of the microchannel assembly cooled power circuit of FIG. 10A;

FIG. 11A is a perspective view of another example microchannel assembly cooled power circuit with integrally formed manifolds in accordance with the present disclosure;

FIG. 11B is an exploded view of the microchannel assembly cooled power circuit of FIG. 11A;

FIG. 12 is a perspective view of a microchannel portion of a microchannel assembly including linear-shaped microchannels in accordance with the present disclosure; and

FIG. 13 is a perspective view of a portion of a microchannel assembly including sinusoidal-shaped microchannels in accordance with the present disclosure.

In the drawings, reference numbers may be reused to identify similar and/or identical elements.

### DETAILED DESCRIPTION

A substrate processing tool may include one or more processing modules for processing substrates. The processing modules may be configured to perform, for example, etch, deposition, and cleaning operations. The substrate processing tool may include one or more AC boxes for powering various circuits, devices and components. Each of the AC boxes may be allocated to one or more modules (e.g., processing modules) and/or systems of the substrate processing tool. Each AC box is configured to satisfy high power requirements and may include AC circuit components and a cooling assembly. As an example, some of the AC circuit components (e.g., solid state relays (SSRs), fuses, and contactors) may be mounted on a printed circuit board (PCB), which may be mounted on a heat exchanger of the cooling assembly. The PCB may be mounted to the heat exchanger via spacers that separate the PCB from the heat exchanger.

The AC circuit components are connected to the PCB and generate heat, which may be absorbed by the heat exchanger. The heat exchanger may include a cooling pad (or block) formed of aluminum and have copper tubing embedded therein for circulating a coolant (e.g., water) to cool the cooling pad. The AC circuit components on the PCB may be in contact with the cooling pad or spaced away from the cooling pad. The copper tubing may be implemented as a process cooling water (PCW) line.

The SSRs on the PCB can be a major heat source generating 65 watts (W), where the PCB of the AC power box may generate a total of 100 W. The AC power box may have a rated capacity of 16.6 kiloWatts (KW). Heat generated by the SSRs is dissipated to process cooling water via the cooling pad and the PCW line. The SSRs may be in contact with the cooling pad. A fan may be used to provide forced convective cooling to ensure operating temperatures of components within the AC box do not exceed maximum operating temperatures of the components. The stated combination of a PCW driven heat exchanger and forced convection maintains the required temperature within the AC box.

Each generation of etch tools are accompanied by higher power requirements to facilitate stringent processes and satisfy more stringent node level requirements (e.g., dimensions of features on a substrate). As an example, node level requirements have decreased from a 40 nanometer (nm) pitch level (or distance between features) to 3-4 nm and rated capacities of AC power boxes have increased to 38.4 KW. In order to satisfy increased power requirements, an AC box and corresponding components may be enlarged with enlarged heat dissipating features. Active cooling of components within the AC box may be achieved using a conventional cooling assembly as described above including a fan and a heat exchanger with a heat sink and cooling channels. The cooling assembly is however bulky, can require a significant amount of energy to run the fan, and has a limited amount of cooling capacity.

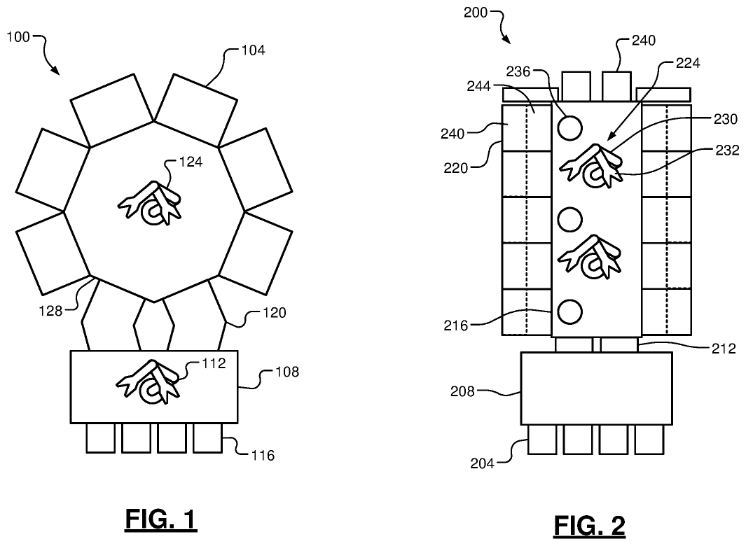

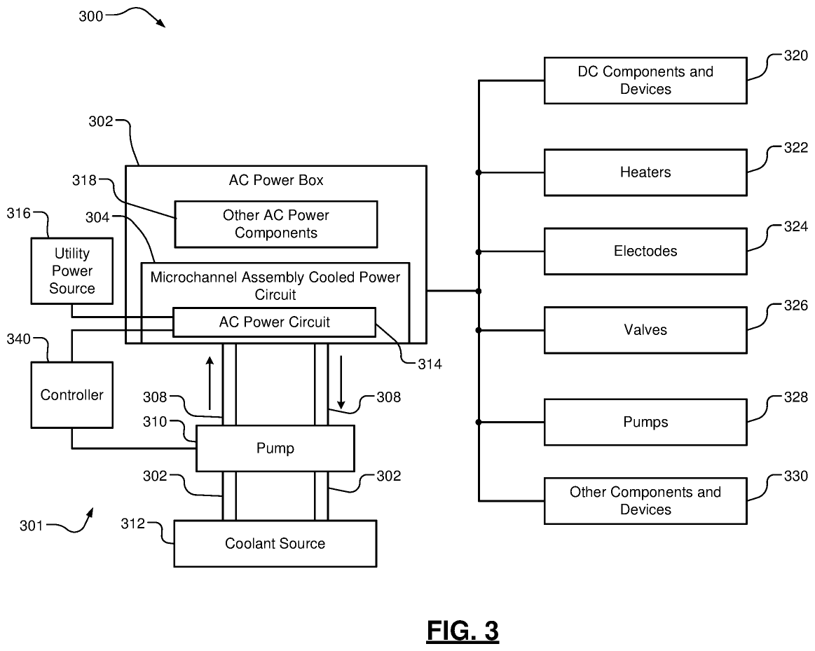

The examples set forth herein include microchannel assembly cooled power circuits that include PCB and microchannel layers. The microchannel layers may be embedded in respective PCBs. The microchannel assembly cooled power circuits do not include cooling fans, are small, and provide increased cooling capacity over traditional heat exchanger designs. The microchannel assembly cooled power circuits may be implemented in AC boxes, which may be included in substrate processing tools to power various components, devices and systems of the substrate processing tools. A couple of example substrate processing tools are shown in FIGS. 1-2. The microchannel assembly cooled power circuits and AC boxes disclosed herein are applicable to other substrate processing tools.

Referring now to FIG. 1, a top-down view of an example substrate processing tool 100 is shown. The substrate processing tool 100 includes processing modules (PMs) 104. For example only, each of the PMs 104 may be configured to perform one or more respective processes on a substrate. Substrates to be processed are loaded into the substrate processing tool 100 via ports of a loading station of an atmosphere-to-vacuum (ATV) transfer module, such as an equipment front end module (EFEM) 108, and then transferred into one or more of the PMs 104. For example, a transfer robot 112 is arranged to transfer substrates from loading stations 116 to airlocks, or load locks, 120, and a robot 124 of a vacuum transfer module 128 is arranged to transfer substrates from the load locks 120 to the various PMs 104. In the example shown in FIG. 1, the substrate processing tool 100 has a circular arrangement. Accordingly, the PMs 104 are arranged azimuthally around the VTM 128. A fabrication room may include several of the substrate processing tools 100.

FIG. 2 shows a plan view of another example configuration of a substrate processing tool 200. The processing tool 200 includes loading stations 204, an equipment front end module (EFEM) 208, load locks 212, and a vacuum transfer module (VTM) 216 arranged in a linear configuration. For example only, the loading stations 204 may be implemented as front opening unified pods (FOUPs). In some examples, the load locks 212 may be fully or partially integrated within the EFEM 208. In other examples, the load locks 212 are arranged outside of and adjacent to the EFEM 208.

The tool 200 includes PMs 220 in a linear arrangement in two parallel rows adjacent to and offset from the VTM 216. The PMs 220 may include substrate processing chambers configured to perform etch, deposition, clean or other treatment operations on substrates. The etching may include dielectric etching (e.g., inductively coupled plasma (ICP) etching) or capacitive etching (e.g., capacitively coupled plasma (CCP) etching).

The VTM 216 may include one or more robots 224 having various configurations. Although shown having one arm 230, each of the robots 224 may have configurations including one, two, or more of the arms 230. In some examples, the robots 224 may include one or two end effectors 232 on each of the arms 230.

The substrate processing tool 200 may include one or more storage buffers 236. The storage buffers 236 are configured to store one or more substrates between processing stages, before or after processing, etc., and/or to store edge rings, covers, and other components of the PMs 220. In other examples, one or more of the storage buffers 236, additional process modules, post-processing modules, and/or other components may be arranged on the end of the VTM 216 opposite the loading stations 204. In some examples, one or more of the EFEM 208, the load locks 212, the VTM 216, and the PMs 220 may have a vertically stacked configuration.

Each of the PMs 220 includes associated internal and external components (not shown) including, but not limited to, radio frequency (RF) generator and power supply circuitry and gas delivery system components. For example, each of the process modules 220 includes an RF generator 240 and a gas box 244 (e.g., including components such as one or more manifolds, valves, flow controllers, etc.). In the substrate processing tool 200 according to the present disclosure, the RF generator 240 and the gas box 244 are arranged above the PM 220. The RF generators 240 and the gas boxes 244 are arranged side-by-side above the process modules 220. The RF generators and gas boxes may be disposed in other arrangements.

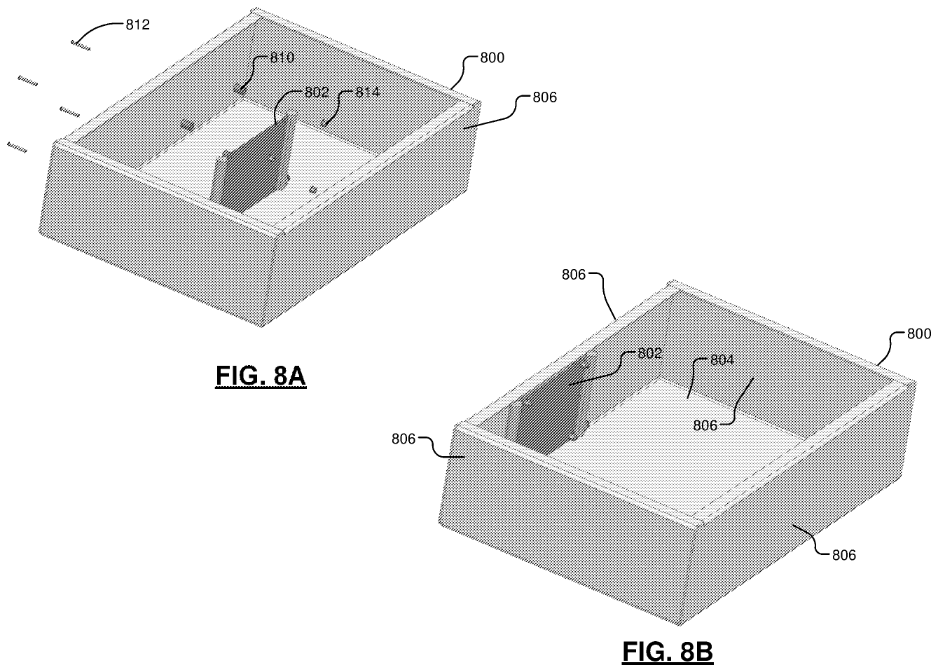

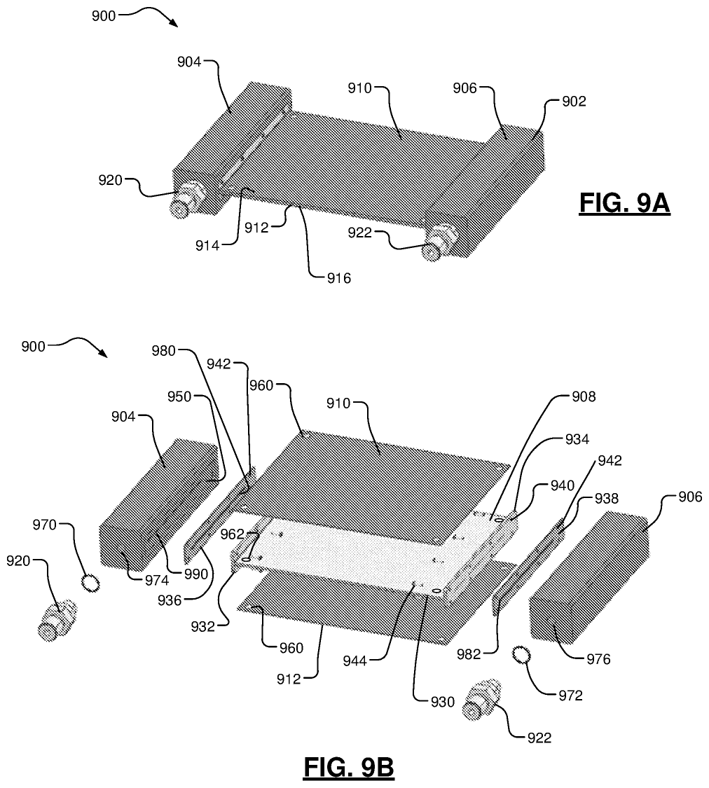

FIG. 3 shows an example power system 300 for a substrate processing tool including a cooling system 301 having an example AC power box 302. The AC power box 302 may be replaced by any of the AC power boxes disclosed herein and may include a microchannel assembly cooled power circuit 304. The microchannel assembly cooled power circuit 304 receives a coolant (e.g., water, an electrically insulating stable fluorocarbon-based fluid including perfluorinated compounds (PFCs), or other coolant) from a coolant source 312 (e.g., a reservoir) via coolant lines (e.g., conduits or hoses) 308. The coolant lines 308 are connected to input and output connectors on the microchannel assembly cooled power circuit 304. The microchannel assembly cooled power circuit 304 provides a compact closed loop arrangement with the lines 308 and the pump 310. Examples of the connectors are shown in FIGS. 9A-13. The coolant lines 308 may be connected to a pump 310, which may be in turn connected to the coolant source 312.

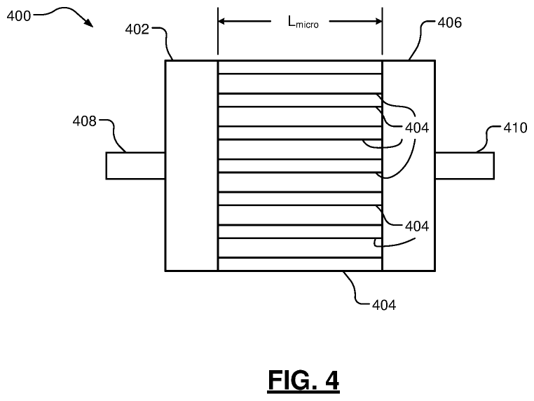

The microchannel assembly cooled power circuit 304 includes an AC power circuit 314 that is cooled by a microchannel assembly. Examples of the microchannel assembly and portions thereof are shown in FIGS. 4-13 along with examples printed circuit board (PCB) layers on which the AC power circuit 314 may be implemented. The AC power circuit 314 may receive utility power from a utility power source 316. The AC power box 302 may include other AC power components, such as capacitors, electrical connectors, etc., which may be connected to the AC power circuit 314.

The AC power box 302 may, as an example, convert 396 volt (V) AC power to 528V AC power having 50-60 Hertz (Hz) frequency and up to 80 Amperes (A) of current. The AC power circuit 314 and the AC power components 318 may, for example, power direct current (DC) components and devices 320, heaters 322, electrodes 324 (e.g., electrodes in showerheads and substrate supports), valves 326, pumps 328, and other components and devices 330. The DC components and devices 320 may include an Ethernet hub DC enclosure. The heaters 322 may include tool heaters, PM heaters, etc. The electrodes 324 may include upper and lower electrodes in PMs. The pumps 328 may include turbo molecular pumps, roughing pumps, water pumps, and/or other vacuum pumps.

The pump 310 and the AC power circuit 314 may be controlled by a controller 340. The controller 340 may control a flow rate of coolant through microchannels of the microchannel assembly of the microchannel assembly cooled power circuit 304. The controller 340 may control power supplied to the power DC components and devices 320, heaters 322, electrodes 324, valves 326, pumps 328, and other components and devices 330.

FIG. 4 shows a microchannel assembly 400 that includes an input manifold 402, microchannels 404 and an output manifold 406. The input manifold 402 may include an input connector 408. The output manifold 406 may include an output connector 410. The connectors 408, 410 may be disposed in various locations on the manifolds 402, 406. The microchannels 404 extend from the input manifold 402 to the output manifold 406. As an example, the microchannels 404 and the manifolds 402, 406 may be formed of plastic and/or other suitable materials.

The number of microchannels N may be selected based on the length L_{micro} of the microchannels 404. As an example, the number of microchannels N may be selected using equations 1-3, where D_{micro} is a diameter of the microchannels, T is temperature of coolant in the microchannels 404, h_{micro} is a thermal convection coefficient, Q is a coolant flow rate, K is temperature in degrees Kelvin, m is meters, W is watts, T_{PCB} is temperature of the PCB, and T_{Fluid} is temperature of coolant passing through the microchannels 404. As an example, Q=67 W, T_{PCB}=60° C., T_{Fluid}=25° C., and D_{micro}=500×10⁻⁶ m. These values are provided only for example purposes and may be different than stated. These values and equations 1-3 are provided for a micro-channel having a circular cross-section, as further defined below.

$$N \times {L}_{micro} = \frac{Q}{π {D}_{micro} {h}_{micro} ( {T}_{PCB} - {T}_{Fluid} )} \qquad ( 1 )$$

$$N \times {L}_{micro} = \frac{1 218.67}{{h}_{micro}} \qquad ( 2 )$$

$${h}_{micro} [ \frac{W}{{m}^{2} K} ] = 1.4886 {Q}^{2} - 3.8583 Q + 1800 \qquad ( 3 )$$

The microchannels 404 may have various different cross-section shapes. A cross-section of a microchannel refers to a lateral slice through the microchannel in a direction perpendicular to a longitudinal length (or longitudinal centerline) of the microchannel. The microchannels 404 may have circular, rectangular, square, oval or other shaped cross sections. In one embodiment, the microchannels 404 have rectangular or oval shaped cross-sections. The rectangular and oval shaped cross-sections provide better heat transfer characteristics than circular cross-section microchannels. The rectangular and oval shaped cross-section microchannels have comparatively high Nusselt numbers for similar dimensions (i.e., length and width of cross-section) of other shaped cross-sections. The Nusselt number may be determined using equation 4, where A is the area of the cross-section of the microchannel, P is the perimeter of the cross-section of the microchannel, I*ₚ is the polar moment of inertia.

$${Nu}_{\sqrt{A}} = 8.47 {π}^{2} {I}_{p}^{*} \frac{\sqrt{A}}{P} \qquad ( 4 )$$

Microchannels having different cross-sections have different aspect ratios. The aspect ratio ε refers to a ratio between width and length dimensions of the cross-sections. As an example, for an aspect ratio ε of 0.25, Nu_{rect}=6.75, Nuₑₗₗᵢₚₛₑ=6, and Nu_{circular}=4. Elliptical and rectangular cross-sections have 50%-60% better heat transfer characteristics as compared to circular cross-sections. The convective heat transfer coefficient h, as represented by equation 5, where k is thermal conductivity of the microchannel and d is hydraulic diameter of the microchannel.

$$h = Nu \times ( \frac{k}{d} ) \qquad ( 5 )$$

The rectangular and oval shaped cross-sections may be manufactured using a direct write assembly method to provide requisite surface roughness using appropriate nozzle shapes for ink laying. The nozzle shapes may include circular, rectangular and oval shaped nozzles to provide circular, rectangular and oval shaped microchannels. The overall heat transfer of a microchannel may be characterized by equation 6, where A is surface area in convection, ΔT is the total temperature increase of coolant as it leaves the output manifold.

$$q = h A ( Δ T ) \qquad ( 6 )$$

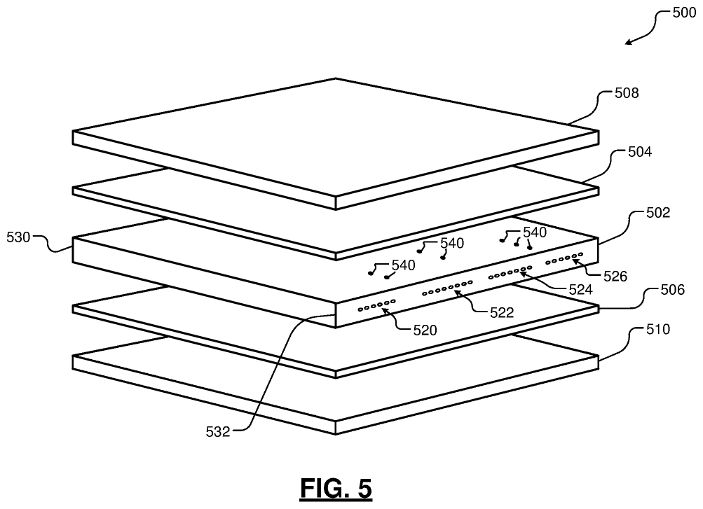

The microchannel assemblies disclosed herein may be manufactured using one or more methods. In one embodiment, a microchannel assembly is manufactured using a direct write assembly method. FIG. 5 shows a portion 500 of a microchannel assembly cooled power circuit that includes a microchannel layer 502, conductive layers 504, 506, and component carrying layers 508, 510. The layers 502, 504, 506, 508, 510 may be referred to as PCB layers of a PCB (or simply layers of a PCB). Although shown separately, the layers 502, 504, 506, 508, 510 may contact each other. The microchannel layer 502 includes sets of microchannels 520, 522, 524, 526, where each set includes multiple microchannels that extend from a first end 530 of the microchannel layer 502, through the microchannel layer 502 to a second end 532 of the microchannel layer 502. The spacing between the sets of microchannels 520, 522, 524, 526 and the distance (or pitch) between adjacent microchannels may be set to adjust the amount of cooling in corresponding areas.

The microchannel assembly cooled power circuit may be formed using a direct write method using fugitive ink inside a resin. For example, a syringe having a micro-nozzle may be used to apply a fugitive organic ink (e.g., wax) to a substrate (e.g., a PCB layer and/or a conductive layer) to provide ink lines (or molds) in the shape of channels to be formed. Resin may then be applied to fill in gaps between the ink lines. Subsequent to the resin hardening, the ink is removed to provide microchannels. This may be done using hot water to remove the wax, when wax is applied. The substrate may be removed from the resin plate and manifolds may then be attached to the inputs and outputs of the microchannels. PCB layers, if not already attached, may be attached to opposing sides of the resin plate. Conductive layers may be disposed between the resin plate and component carrying layers, as shown. The resin plate performs as a heat sink and transfers thermal energy from the conductive layers and the component carrying layers to a coolant passing through the microchannels. The resin plate may be formed of, for example, acrylonitrile butadiene styrene (ABS).

Other manufacturing methods may be used to form the microchannel assembly cooled power circuit of FIG. 5 and other microchannel assembly cooled power circuits disclosed herein. The manufacturing methods include: stereolithography via which manifolds and/or a multichannel layer, member and/or plate may be formed of resin; multi-jet fusion (MJF) via which manifolds and/or a multichannel layer, member and/or plate may be formed of nylon; and selective laser melting (SLM) via which manifolds and/or a multichannel layer, member and/or plate may be formed of stainless steel (SST) or an aluminum alloy, such as an age-hardening cast aluminum alloy (e.g., AISi10Mg).

The layers 502, 504, 506, 508, 510 may be attached to each other using epoxy and/or fasteners. The microchannel layer 502 is disposed between the PCB layers 504, 508 and the PCB layers 506, 510 and for this reason is referred to as being embedded in a PCB to maximize heat dissipation. The microchannel layer 502, which may be formed of a resin, is “sandwiched” between the two adjacent conductive layers 504, 506, which are in turn sandwiched between the two component carrying layers 508, 510. The conductive layers 504, 506 may include conductive trace patterns formed of, for example, copper. The conductive layers 504, 506 may be used to connect various circuit components mounted on the component carrying layers 508, 510. The conductive layers 504, 508 may include traces, some of which being at a ground reference potential and/or at one or more source voltage potentials. The component carrying layers 508, 510 may be formed of a glass fiber epoxy laminate material.

The stack-up arrangement of the layers 502, 504, 506, 508, 510 aids in dissipating heat from SSRs and other circuit components. This arrangement has low thermal resistance and high heat dissipation capacity (e.g., 750 watts/centimeter squared (W/cm²)), as compared to a tradition heat exchanger design, which is typically 70-80 W/cm². The form factor of the microchannel assembly cooled power circuit is small and tightly coupled with the heat source thereby minimizing thermal resistance given close proximity of components. The microchannel assembly cooled power circuit may eliminate the need for a secondary forced convective medium (e.g., a fan) for additional heat dissipation. The secondary forced convective medium contributes to about 18-20% of the total heat load dissipation when supplemented by a conventional heat exchanger, with a 25° C. and a 1 gallon per minute (GPM) flow rate for the heat exchanger. The use of the fan also requires that a heating ventilation and air-conditioning (HVAC) system cooling an environment of the substrate processing tool run to maintain temperature of the environment, which increases operating costs. By elimination of the fan and increased heat transfer to the coolant, a reduction in HVAC system operating costs and a reliable cooling system are provided.

The low thermal resistance and the high heat dissipation enables a small overall footprint of the microchannel assembly cooled power circuit. The elimination of a fan and replacement of a conventional heat exchanger with embedded and/or centrally disposed microchannels provides approximately a 60% volume reduction. This volume reduction is associated with the outer dimensions of the microchannel assembly cooled power circuit (or combined cooling assembly and power circuit). As an example, a traditional cooling assembly including a tradition heat exchanger may consume 114.3 cubic inches of space, whereas the example embodiments may consume 41 cubic inches of space and thereby provide a 64% net reduction in volume. The elimination of the fan also saves the 18 W of power typically used to run the fan.

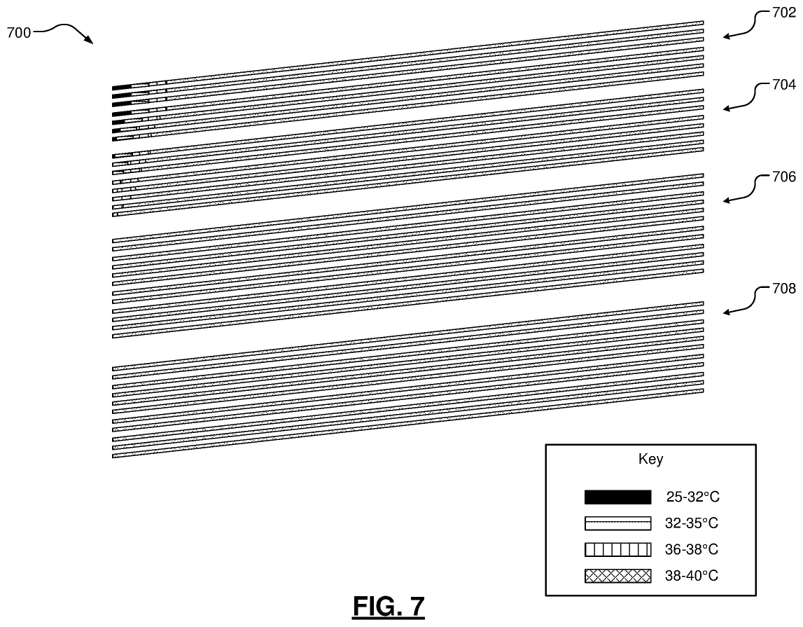

The compact microchannel assembly cooled power circuit may be disposed in a hermetically sealed AC box and the corresponding microchannel assembly may be configured with a unitary structure. The stated hermetically sealed AC box and unitary structure configuration, as further described below with respect to FIGS. 8A-8B, aid in providing ingress protection against dust and protection against liquid exposure.

The microchannel assembly cooled power circuits disclosed herein may include layers stacked similarly as the layers of the microchannel assembly cooled power circuit. The component carrying layers may include various circuit components including SSRs, fuses, contactors and other circuit components, which may be closely arranged to provide a high-density of components. This high-density of components is enabled due to the high heat dissipation capacity of the microchannel assemblies. The outer dimensions of the AC boxes disclosed herein are minimal due to the compact arrangements and high density of components packaged onto the component carrying layers. The microchannel assembly cooled power circuits are scalable in size for various applications.

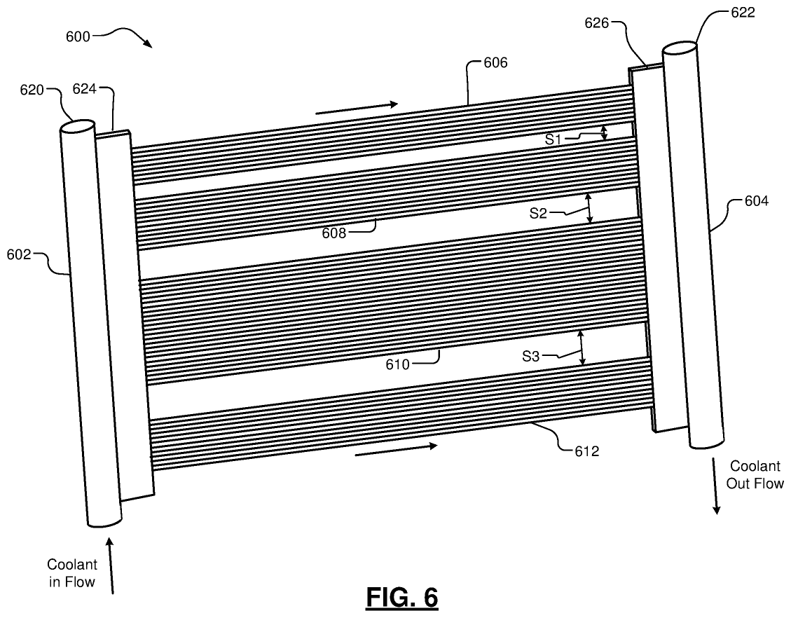

FIG. 6 shows a microchannel assembly 600 illustrating sets of microchannels disposed between a pair of manifolds 602, 604. Envelopes (or inner boundary dimensions) of each of the microchannels and the flow of coolant is represented by sets of lines 606, 608, 610, 612, where each of the sets of lines 606, 608, 610, 612 includes a different group of microchannels having different amounts of separation between the sets. Example separation amounts S1, S2, S3 are shown between the sets of lines 606, 608, 610, 612. In FIG. 6 the physical microchannel layer (or plate) is not shown. The pitch (or separation between adjacent microchannels within each set) may also be adjusted to achieve the desired amount of cooling in a certain area. The representative coolant flow paths shown by lines 606, 608, 610, 612 may be surrounded by resin or other material as described above to provide the microchannels.

In the example shown, the manifolds 602, 604 include tubular ends 620, 622 and plates 624, 626. The tubular ends 620, 622 may be connected to input and output connectors for receiving and outputting coolant. The plates 624, 626 may include microchannels corresponding to the microchannels extending from the plates 624 to the plate 626.

Referring now to FIGS. 5-6, the microchannel layer 502, which may be configured including sets of microchannels spaced apart as represented by FIG. 6, may include electrically conductive vias extending through the microchannel layer 502 between the conductive layers 504, 506 to connect terminals and/or other components mounted on the component carrying layer 508 to terminals and/or other components mounted on the component carrying layer 510. Example vias 540 are shown in FIG. 5 and are disposed in spaces between the sets of microchannels 520, 522, 524, 526.

FIG. 7 shows a temperature distribution diagram 700 for a microchannel assembly similar to that shown in FIG. 6. Sets of lines 702, 704, 706, 708 are shown representing temperatures of coolant line paths of microchannels of the microchannel assembly. As shown, the coolant is between approximately 25° C.-40° C. illustrating that the coolant remains at a cool temperature during operation. As an example, the flow rate may be 300 milliliters per minute (mlpm), the inlet temperature may be 25° C., and a pressure drop ΔP of the coolant across the microchannels may be 50 Pascals at 300 mlpm or 0.007 pounds per square inch (psi). As another example, the microchannel assembly may extract 67 W of energy provided the coolant flow rate is 300 mlpm and the inlet temperature is 25° C. or less. The stated flow rate, pressure, temperature and dissipation valves are provided for example purposes only and may be different, especially for different sized and shaped microchannels.

FIGS. 8A-B show an AC power box 800 including a microchannel assembly cooled power circuit 802. The AC power box 800 is shown having a bottom wall 804 and sidewalls 806 and may include a top wall (not shown). The AC power box 800 may be hermetically sealed. The microchannel assembly cooled power circuit 802 may be mounted to one of the sidewalls 806 as shown with spacers 810, and fasteners 812. The fasteners may include bolts 812 with nuts 814. The bolts 812 extend through holes in a sidewall, holes in the spacers, and holes in component carrying layers, conductive layers and microchannel layers of the microchannel assembly cooled power circuit 802. The nuts 814 are threaded onto the bolts 812 to hold the stated elements being fastened in place. The spacers 810 separate the microchannel assembly cooled power circuit 802 from the sidewall 806.

FIGS. 9A-B show a microchannel assembly cooled power circuit 900 that includes: a microchannel assembly 902 including manifolds 904, 906 and a microchannel member 908 including microchannels; and component carrying layers 910, 912. The component carrying layers 910, 912 are shown without electronic components mounted thereon, but in use do include electronic components mounted thereon. The electronic components may be mounted on a first exterior surface 914 of the first component carrying layer 910 and on an opposing surface 916 of the second component carrying layer 912. The component carrying layers 910, 912 are mounted on opposing sides of the microchannel member 908. The manifolds 904, 906 may include connectors 920, 922, which may be threaded into the manifolds 904, 906. Each of the component carrying layers 910, 912 may be implemented as one or more PCB layers, a combination of component carrying layers and conductive layers (not shown), or as a PCB. In one embodiment, conductive layers (not shown) are disposed between the component carrying layers 910, 912 and the microchannel member 908. In another embodiment, two PCBs are disposed on opposite sides of the microchannel member 908.

In an embodiment, the microchannel member 908 is a single ‘H’-shaped component having a center member 930 and outer flanges 932, 934. Distances between the flanges 932, 934 may vary depending on, for example, the size and lengths of the component carrying layers 910, 912. The center member 930 may be referred to as a plate or layer. The component carrying layers 910, 912 are mounted on opposing sides of the center member 930. The microchannel member 908 extends between and is connected to the manifolds 904, 906. The outer flanges 932, 934 may extend perpendicular to the center member 930. Gaskets 936, 938 are disposed between the manifolds 904, 906 and microchannel member 908. The flanges 932, 934 and the gaskets 936, 938 include holes 940, 942 through which fasteners 944 may extend and be screwed into the manifolds 904, 906. The manifolds 904, 906 include recessed inner sections (one recessed inner section 950 of the manifold 904 is shown), which receive the gaskets 936, 938 and flanges 932, 934.

The component carrying layers 910, 912 are attached to the microchannel member 908 via fasteners (e.g., the fasteners shown in FIG. 8A), which extend through holes 960, 962 in the component carrying layers 910, 912 and the microchannel member 908 to attach to a sidewall of an AC box. The connectors 920, 922 may have respective O-rings 970, 972 that seal the connectors 920, 922 to the manifolds 904, 906. The connectors 920, 922 are received in holes 974, 976 of the manifolds 904, 906.

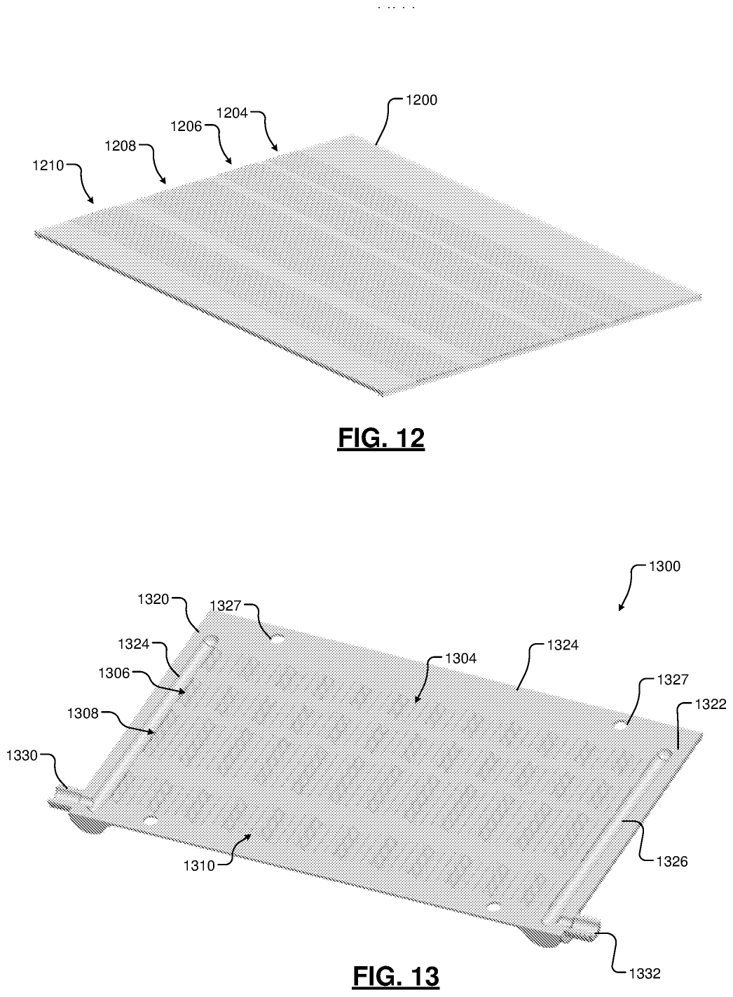

Microchannels may extend through the center member 930 and through the flanges 932, 934. The microchannels may be linear-shaped or may have a different pattern, such as a sinusoidal-shaped pattern. Example linear and sinusoidal-shaped patterns are shown in FIGS. 12 and 13. The microchannels may be spaced apart as described above, and/or have other spacings and/or groupings. Each of the gaskets 936, 938 may include a slit (slits 980, 982 are shown), and/or one or more other holes corresponding to ends of the microchannels in the center member 930. Each of the manifolds 904, 906 may include one or more passages corresponding to the holes in a corresponding one of the gaskets 936, 938 and the corresponding ends of the microchannels. The one or more passages of the manifold 904 are represented by a slot 990.

The manifolds 904, 906 may be formed of high density poly ethylene (HDPE). The gaskets 936, 938 may be implemented as rubber gaskets. These are a couple of material examples, other suitable materials may be used.

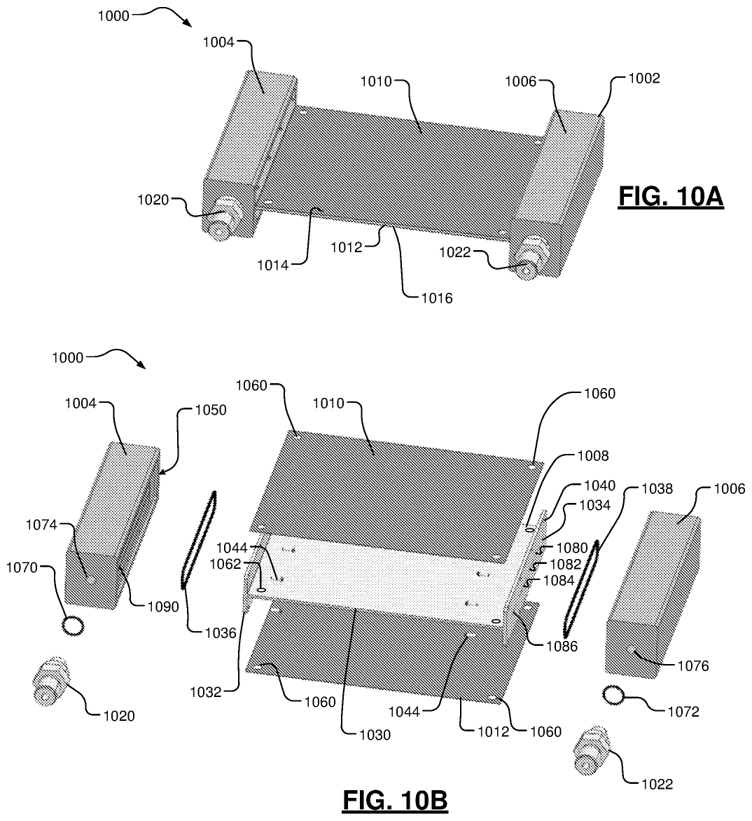

FIGS. 10A-B show a microchannel assembly cooled power circuit 1000 that is similar to the microchannel assembly cooled power circuit 900 of FIGS. 9A-B, but include O-ring sealed manifolds rather than gasket sealed manifolds. The microchannel assembly cooled power circuit 1000 includes: a microchannel assembly 1002 including manifolds 1004, 1006 and a microchannel member 1008 including microchannels; and component carrying layers 1010, 1012. The component carrying layers 1010, 1012 are shown without electronic components mounted thereon, but in use do include electronic components mounted thereon. The electronic components may be mounted on a first exterior surface 1014 of the first component carrying layer 1010 and on an opposing surface 1016 of the second component carrying layer 1012. The component carrying layers 1010, 1012 are mounted on opposing sides of the microchannel member 1008. The manifolds 1004, 1006 may include connectors 1020, 1022, which may be threaded into the manifolds 1004, 1006.

Each of the component carrying layers 1010, 1012 may be implemented as one or more PCB layers, a combination of component carrying layers and conductive layers (not shown), or as a PCB. In one embodiment, conductive layers (not shown) are disposed between the component carrying layers 1010, 1012 and the microchannel member 1008. In another embodiment, two PCBs are disposed on opposite sides of the microchannel member 1008.

In an embodiment, the microchannel member 1008 is a single ‘H’-shaped component having a center member 1030 and to outer flanges 1032, 1034. The center member 1030 may be referred to as a plate or layer. The component carrying layers 1010, 1012 are mounted on opposing sides of the center member 1030. The microchannel member 1008 extends between and is connected to the manifolds 1004, 1006. O-rings 1036, 1038 are disposed between the manifolds 1004, 1006 and microchannel member 1008. The flanges 1032, 1034 include holes 1040 through which fasteners 1044 may extend and be screwed into the manifolds 1004, 1006. The manifolds 1004, 1006 include recessed inner sections (one recessed inner section 1050 of the manifold 1004 is shown), which receive the O-rings 1036, 1038 and flanges 1032, 1034.

The component carrying layers 1010, 1012 are attached to the microchannel member 1008 via fasteners (e.g., the fasteners shown in FIG. 8A), which extend through holes 1060, 1062 in the component carrying layers 1010, 1012 and the microchannel member 1008 to attach to a sidewall of an AC box. The connectors 1020, 1022 may have respective O-rings 1070, 1072 that seal the connectors 1020, 1022 to the manifolds 1004, 1006. The connectors 1020, 1022 are received in holes 1074, 1076 of the manifolds 1004, 1006.

Microchannels may extend through the center member 1030 and through the flanges 1032, 1034. The microchannels may be linear-shaped or may have a different pattern, such as a sinusoidal-shaped pattern. Groups of microchannels of the center member 1030 are represented by slots 1080, 1082, 1084, 1086. Example linear and sinusoidal-shaped patterns are shown in FIGS. 12 and 13. The microchannels may be spaced apart as described above, and/or have other spacings and/or groupings. Each of the manifolds 1004, 1006 may include one or more passages corresponding to ends of the microchannels. The one or more passages of the manifold 1004 are represented by a slot 1090. The manifolds 1004, 1006 may be formed of HDPE.

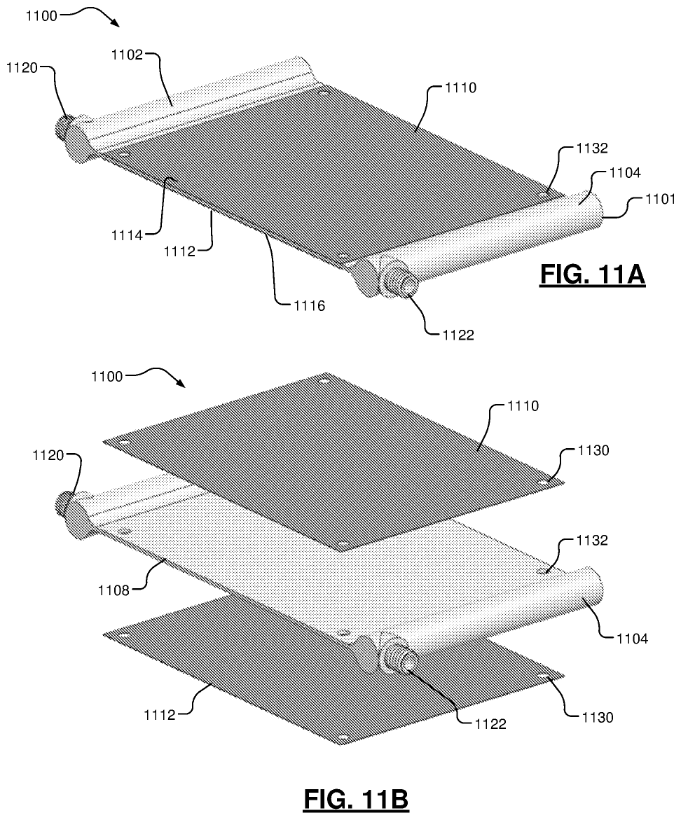

FIGS. 11A-B show perspective views of another example microchannel assembly cooled power circuit 1100 with integrally formed manifolds 1102, 1104. The microchannel assembly cooled power circuit 1100 includes: a microchannel assembly 1101 including manifolds 1102, 1104 and a microchannel member 1108 including microchannels; and component carrying layers 1110, 1112. The component carrying layers 1110, 1112 are shown without electronic components mounted thereon, but in use do include electronic components mounted thereon. The microchannels extend from the input manifold 1102 to the output manifold 1104. The electronic components may be mounted on a first exterior surface 1114 of the first component carrying layer 1110 and on an opposing surface 1116 of the second component carrying layer 1112. The component carrying layers 1110, 1112 are mounted on opposing sides of the microchannel member 1108. The microchannel member 1108 may be referred to as a plate and/or layer.

Each of the component carrying layers 1110, 1112 may be implemented as one or more PCB layers, a combination of component carrying layers and conductive layers (not shown), or as a PCB. In one embodiment, conductive layers (not shown) are disposed between the component carrying layers 1110, 1112 and the microchannel member 1108. In another embodiment, a PCB is disposed on opposite sides of the microchannel member 1108.

The manifolds 1104, 1106 may include protruding connecting portions 1120, 1122, which may be threaded. The microchannel assembly 1101 may be formed as a single component including the manifolds 1102, 1104, the microchannel member 1108, and the protruding connecting portions 1120, 1122. This unitary structure eliminates chances of leaks between manifolds and a microchannel member, since the manifolds and the microchannel member are integrally formed as a single component. The microchannel member 1108 includes microchannels similar to that shown in FIGS. 4, 5, 9B, 10B, 12 and 13. The protruding connecting portions 1120, 1122 may be connected to connectors, which may be screwed on and sealed by O-rings to the protruding connecting portions 1120, 1122. The connectors may be similar to the connectors 920, 922, 1020, 1022 of FIGS. 9A-10B, expect have female threaded ends configured to be screwed onto the protruding connecting portions 1120, 1122. The component carrying layers 1110, 1112 may be held on the microchannel member 1108 via fasteners extending through holes 1130, 1132 to attach to a sidewall of an AC box.

FIG. 12 shows a microchannel portion 1200 of a microchannel assembly including sets of linear-shaped microchannels 1204, 1206, 1208, 1210. The sets of linear-shaped microchannels 1204, 1206, 1208, 1210 include respective numbers of microchannels. Although four sets of microchannels are shown, a different number of sets may be included. The number of microchannels in each of the sets of microchannels may be the same or different, as shown. The spacing between the microchannels in each set of microchannels may be the same or different than the spacing between the microchannels in each other set of microchannels. In the example shown, the spacing between microchannels in each set of microchannels is the same. The spacing between adjacent sets of microchannels may be the same or different, as shown. The microchannel assembly may be configured similarly as the microchannel assembly 1101 of FIG. 11. Although not shown in FIG. 12, the microchannel assembly includes manifolds with input and output protruding connecting portions.

FIG. 13 shows a portion 1300 of a microchannel assembly including sets of sinusoidal-patterned (or wave-patterned) microchannels 1304, 1306, 1308, 1310. The microchannel assembly may be configured similarly as the microchannel assembly 1101 of FIG. 11 and may include manifolds (or manifold ends) 1320, 1322 and a microchannel member 1324, as shown. The microchannel member 1324 extends between the manifolds 1320, 1322 and includes the microchannels 1304, 1306, 1308, 1310 and may include holes 1327 through fasteners may extend for connecting PCB layers and a sidewall of an AC box. The manifold ends 1320, 1322 include respective channels 1324, 1326 that extend laterally across ends of the microchannels 1304, 1306, 1308, 1310 and supply coolant or receive coolant from the microchannels 1304, 1306, 1308, 1310. The manifolds of the microchannel assembly of FIG. 12, which are not shown in FIG. 12, may be configured similarly as the manifold ends 1320, 1322 of the manifold assembly of FIG. 13. The manifold ends 1320, 1322 include protruding connecting portions 1330, 1332.

The microchannels 1304, 1306, 1308, 1310 have a wave-shaped pattern such that the microchannels have increased length for a given distance between the channels 1324, 1326, as compared to linear-shaped microchannels for the same given distance. The increased length increases the amount of coolant in the microchannels at any moment in time and the cooling capacity of the microchannels and the amount of heat dissipation provided by the microchannels. The sinusoidal-patterned microchannels are able to absorb thermal energy at an increased rate as compared to the linear-shaped microchannels. Although four sets of sinusoidal-patterned microchannels are shown, a different number of sets may be included. The number of microchannels in each of the sets of sinusoidal-patterned microchannels may be the same or different, as shown. The spacing between the sinusoidal-patterned microchannels in each set of sinusoidal-patterned microchannels may be the same or different than the spacing between the sinusoidal-patterned microchannels in each other set of sinusoidal-patterned microchannels. In the example shown, the spacing between sinusoidal-patterned microchannels in each set of sinusoidal-patterned microchannels is the same. The spacing between adjacent sets of sinusoidal-patterned microchannels may be the same or different, as shown.

The microchannels of the embodiments of FIGS. 4, 5 and 8A-13 may have circular, oval (or elliptical), and/or rectangular cross-sections. As an example, a rectangular cross-section may have a 2000 micrometers (μm) length and a 500 μm width (or height). A circular cross-section may have a 500 μm diameter. An oval cross-section may have an aspect ratio of 1:0.25 with a major dimension of 2000 μm and a minor dimension of 500 μm. By having the circular, oval, and rectangular cross-sections have the same width (or height) dimension, there is no net width (or height) increase in the microchannel member. The width (or height) of the microchannel member is a dimension measured in a direction parallel to the channels 1324, 1326 and perpendicular to a flow direction of coolant from the inlet channel 1324 to the outlet channel 1326 of FIG. 13.

The microchannel layers and members disclosed herein may be configured and the flow rate through the microchannels may be set to provide laminar flow or turbulent flow of coolant through the microchannels. Laminar flow refers to flow taking place along constant streamlines, whereas turbulent flow refers to chaotic flow patterns. The more chaotic the flow, the more heat transfer to the coolant. The flow rate of coolant may be adjusted to provide laminar flow or turbulent flow. When the flow rate is less than a first predetermined threshold, then laminar flow may be provided and when above a second predetermined threshold, then turbulent flow may be provided. Turbulent flow provides increased cooling over laminar flow due to the ability of the coolant to better absorb thermal energy when traveling through the microchannels.

As an example, laminar flow may be provided when the Reynolds number Re of the microchannels is less than 1000 and a turbulent flow may be provided when the Reynolds number is greater than 2500. The Reynolds number range of 1500-2500 is a transitional range in which the coolant flow may be laminar or turbulent. A Reynolds number range of 1000-1500 refers to an unclassified range in which coolant flow may be laminar or turbulent. The Reynolds number Re may be set, determined and/or satisfied by the controller 340 of FIG. 3. The controller 340 may determine whether to operate in a laminar flow mode or a turbulent flow mode and set the flow rate and/or the Reynolds number, accordingly. Example relationships between the flow rate and the Reynolds number Re are provided by equations 6-8, where v is average velocity of fluid, d is hydraulic diameter of the microchannel, s is seconds, p is density and μ is dynamics viscosity.

$$v \text{:} \text{=} \frac{q}{\frac{22}{7} {d}^{2}} = 6.364 \frac{m}{s} \qquad ( 6 )$$

$$Re := ρ \cdot v \cdot \frac{d}{μ} = 3166.6 \; 86 \qquad ( 7 )$$

$$Re = \frac{ρ v d}{μ} \qquad ( 8 )$$

Example values are provided by equations 9-14, where u is water dynamic viscosity, kg is kilograms, m is meters, l is length of microchannel, Pa is Pascals and one Pascal is equal to one newton per square meter of pressure, ρ is density of water, q is a flow rate, mL is milliliters, and min is minutes.

$$μ : = 0.001003 \frac{kg}{ms} \qquad ( 9 )$$

$$l := 0.16 m \qquad ( 10 )$$

$$d := 500 \cdot {10}^{- 6} m \qquad ( 11 )$$

$$dP := 50 Pa \qquad ( 12 )$$

$$ρ : = 998.23 \frac{kg}{{m}^{3}} \qquad ( 13 )$$

$$q := 300 \frac{mL}{min} \qquad ( 14 )$$

The examples disclosed herein include integrated microchannel assemblies with reduced overall footprints that have high dissipation capacity for a given heat load. The disclosed stack up of layers, microchannel members, PCBs, etc. provide thin arrangements that are easily mounted to sidewalls of AC boxes to allow for increase space within the AC boxes. The compact thin arrangements have lower thermal mass and provide ten times the amount of heat dissipation as traditional designs. The examples are scalable and may use various types of coolants. The examples may include microchannels with varying numbers of microchannels, spacing between microchannels, spacing between sets of microchannels, microchannels with different shaped cross-sections, and microchannels with different types of path extending patterns (e.g., linear or sinusoidal patterns) between manifolds.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A cooling system for a power circuit of a substrate processing tool, the cooling system comprising:
a microchannel assembly comprising
an input manifold,
an output manifold, and
a microchannel layer comprising a plurality of microchannels extending from the input manifold to the output manifold and configured to pass a coolant from the input manifold to the output manifold; and
a printed circuit board comprising at least one component carrying layer, wherein the at least one component carrying layer is attached to the microchannel layer between the input manifold and the output manifold, and wherein the at least one component carrying layer comprises the power circuit including a plurality of electrical components configured to power one or more electrical components of the substrate processing tool,
wherein the microchannel layer is disposed between layers of the printed circuit board such that the microchannel layer is embedded in the printed circuit board.

2. (canceled)

3. The cooling system of claim 1, wherein the at least one component carrying layer comprises:
a first component carrying layer disposed on a first side of the microchannel layer; and
a second component carrying layer disposed on a second side of the microchannel layer opposite the first side.

4. The cooling system of claim 3, further comprising:
a first conductive layer comprising a first pattern of conductive traces and disposed between the microchannel layer and the first component carrying layer; and
a second conductive layer comprising a second pattern of conductive traces and disposed between the microchannel layer and the second component carrying layer.

5. The cooling system of claim 1, further comprising an alternating current box,
wherein the microchannel assembly and the printed circuit board are mounted on a same inner sidewall of the alternating current box.

6. The cooling system of claim 5, wherein the alternating current box is hermetically sealed.

7. The cooling system of claim 1, wherein:
the plurality of microchannels comprises a plurality of sets of microchannels including a first set of microchannels and a second set of microchannels; and
distances between two adjacent sets of the plurality of sets of microchannels are greater than distances between microchannels in each of the plurality of sets of microchannels.

8. The cooling system of claim 7, wherein a number of microchannels in the first set of microchannels is different from a number of microchannels in the second set of microchannels.

9. The cooling system of claim 7, wherein a number of microchannels in the first set of microchannels is same as a number of microchannels in the second set of microchannels.

10. The cooling system of claim 7, wherein a distance between first adjacent sets of the plurality of sets of microchannels is different from a distance between second adjacent sets of the plurality of sets of microchannels.

11. The cooling system of claim 7, wherein a distance between first adjacent sets of the plurality of sets of microchannels is same as a distance between second adjacent sets of the plurality of sets of microchannels.

12. The cooling system of claim 7, further comprising:
a plurality of conductive layers,
wherein the at least one component carrying layer comprises a plurality of component carrying layers, and
wherein the plurality of conductive layers are disposed between the microchannel layer and the plurality of component carrying layers; and
vias extending through the microchannel layer in spaces between sets of the plurality of microchannels and contacting conductive traces of the plurality of conductive layers.

13. The cooling system of claim 1, wherein the plurality of microchannels are linear-shaped.

14. The cooling system of claim 1, wherein the plurality of microchannels have a sinusoidal shape.

15. The cooling system of claim 1, wherein the input manifold, the output manifold and the microchannel layer form a unitary structure.

16. The cooling system of claim 1, further comprising:
a pump configured to circulate the coolant through the microchannel assembly; and
a controller configured to select operating in a laminar flow mode or a turbulent flow mode and operate the pump accordingly.

17. A cooling system for a power circuit of a substrate processing tool, the cooling system comprising:
a microchannel assembly comprising
an input manifold,
an output manifold, and
a microchannel member comprising a plurality of microchannels extending from the input manifold to the output manifold and configured to pass a coolant from the input manifold to the output manifold; and
a plurality of printed circuit board layers comprising a first printed circuit board layer and a second printed circuit board layer, wherein the first printed circuit board layer is disposed on a first side of the microchannel member, wherein the second printed circuit board layer is disposed on a second side of the microchannel member, and wherein the plurality of printed circuit board layers comprise the power circuit including a plurality of electrical components configured to power one or more electrical components of the substrate processing tool,
wherein
the microchannel assembly includes only a single microchannel layer cooling a first printed circuit board and a second printed circuit board,
the first printed circuit board comprising the first printed circuit board layer, and
the second printed circuit board comprising the first printed circuit board layer.

18. The cooling system of claim 17, wherein:
the first printed circuit board layer comprises a first component carrying layer and a first conductive layer; and
the second printed circuit board layer a second component carrying layer and a second conductive layer.

19. The cooling system of claim 18, wherein:
the first conductive layer comprises a first pattern of conductive traces; and
the second conductive layer comprises a second pattern of conductive traces.

20. The cooling system of claim 17, wherein the microchannel member comprises:
a plurality of flanges configured to connect to the input manifold and the output manifold; and
a center member extending between the plurality of flanges and comprising the plurality of microchannels.

21. The cooling system of claim 20, wherein the plurality of flanges and the center member are integrally formed as a single component.

22. The cooling system of claim 20, wherein:
the plurality of flanges extend perpendicular relative to the center member; and
the plurality of flanges and the center member have an ‘H’-shaped cross-section.

23. The cooling system of claim 20, further comprising a plurality of gaskets disposed between the plurality of flanges and the input manifold and the output manifold.

24. The cooling system of claim 20, further comprising a plurality of O-rings disposed between the plurality of flanges and the input manifold and the output manifold.

25. The cooling system of claim 17, wherein the input manifold, the output manifold and the microchannel member are integrally formed as a single component.

26. The cooling system of claim 17, wherein the plurality of microchannels are linear-shaped.

27. The cooling system of claim 17, wherein the plurality of microchannels have a sinusoidal shape.

28. The cooling system of claim 17, further comprising:
a pump configured to circulate the coolant through the microchannel assembly; and
a controller configured to select operating in a laminar flow mode or a turbulent flow mode and operate the pump accordingly.

29. The cooling system of claim 17, comprising the first printed circuit board and the second printed circuit board.

30. A cooling system for a power circuit of a substrate processing tool, the cooling system comprising:
a microchannel assembly comprising
an input manifold,
an output manifold, and
a microchannel member comprising a plurality of microchannels extending from the input manifold to the output manifold and configured to pass a coolant from the input manifold to the output manifold; and
a plurality of printed circuit board layers comprising a first printed circuit board layer and a second printed circuit board layer, wherein the first printed circuit board layer is disposed on and contacts a first side of the microchannel member, wherein the second printed circuit board layer is disposed on and contacts a second side of the microchannel member, and wherein the plurality of printed circuit board layers comprise the power circuit including a plurality of electrical components configured to power one or more electrical components of the substrate processing tool.
